(19) United States
(12) Patent Application Publication
(10) Pub. No.: US 2017/0011934 A1
(43) Pub. Date: Jan. 12, 2017

(54) FABRICATING PROCESS FOR REDISTRIBUTION LAYER

(71) Applicant: Dyi-Chung HU, Hsinchu (TW)

(72) Inventor: Dyi-Chung HU, Hsinchu (TW)

(21) Appl. No.: 15/200,135

(22) Filed: Jul. 1, 2016

Related U.S. Application Data
(60) Provisional application No. 62/190,863, filed on Jul. 10, 2015.

(51) Int. Cl. H01L 21/48; H01L 23/00; H01L 21/52

(52) U.S. Cl. CPC H01L 21/4846; H01L 21/4853; H01L 21/486; H01L 21/52; H01L 24/11; H01L 24/03; H01L 2224/02373; H01L 2224/1146

(57) ABSTRACT

A metal sputtering or metal evaporating process is adopted in an initial fabricating step to fabricate a plurality of metal pads without having substantial dimensional change during fabrication. So that a bottom side of the plurality of metal pads is adapted to electrically couple to a nanochip in a later process. In addition, at least a first fan out circuitry is then built up on a top side of the plurality of metal pads. The bottom side of the redistribution layer is made adapted to electrically couple to a nanochip (Chip side), and the top side of the redistribution layer is made adapted to electrically couple to a printed circuit board side (PCB side) which has a plurality of top metal pads and is made adapted to electrically couple to a mother board in a later process.

### BACKGROUND

Technical Field

The present invention relates to a fabricating process for a redistribution layer adapted to nanochip package, especially for a redistribution layer fabricating process using metal sputtering or metal evaporating to fabricate a plurality of dimensional stable metal pads, a bottom side of the metal pads is made adapted to electrically couple to a nanochip.

### DESCRIPTION OF RELATED ART

FIGS. 1A˜1C show a prior art fabricating process

FIG. 1A shows a traditional process for fabricating an initial metal pad

FIG. 1A shows a temporary carrier 10 is prepared. An adhesive layer 11 is formed on a top surface of the temporary carrier 10. A seed layer 112 is configured on a top surface of the adhesive layer 11. A patterned photoresist layer 12 is formed on a top surface of the seed layer 112. A plurality of grooves is formed in the patterned photoresist layer 12. A metal pad 15 is formed in each of the grooves.

FIG. 1B shows the photoresist layer 12 is stripped.

FIG. 1C shows the seed layer 112 is stripped. During the stripping, the dimension of the metal pad 15 is shrinkage due to chemical etching. The shrinkage of a thickness d over the metal pad 15 is shown as an example. The tiny etching shrinkage of the dimension for the metal pad does not affect too much in earlier years, however it becomes a critical issue when the semiconductor technology moves towards micron technology.

### BRIEF DESCRIPTION OF THE DRAWINGS

FIGS. 1A˜1C show a prior art fabricating process

FIGS. 2˜14 show a fabricating process for a redistribution layer according to the present invention.

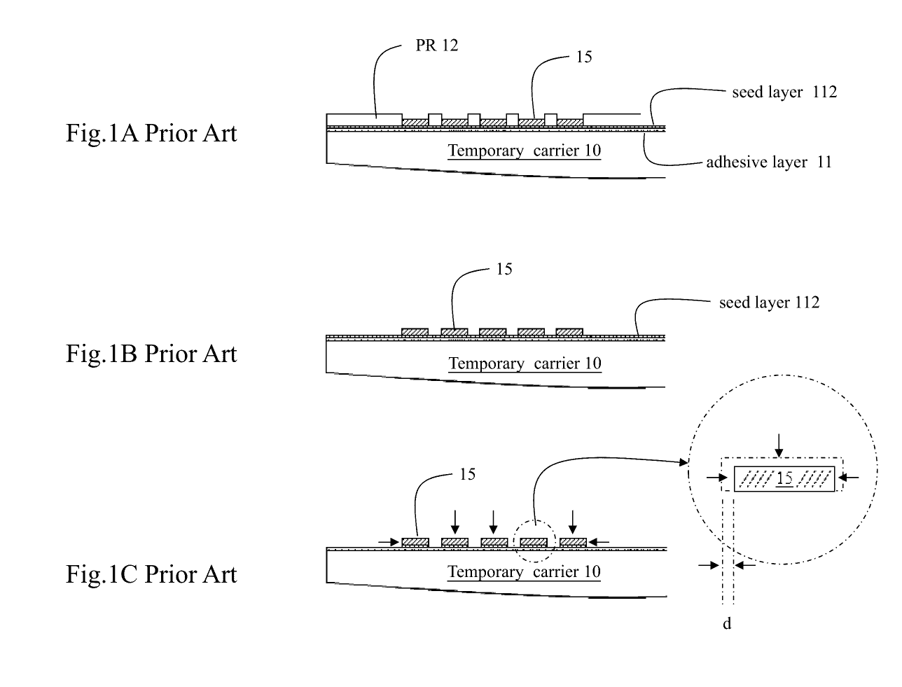

### DETAILED DESCRIPTION OF THE INVENTION

Semiconductor industry is moving towards nanotechnology that requires extremely fine circuit and extremely fine metal pads. A redistribution layer is made to have a first side with fine dimension's metal pads for electrically coupled to a nanochip in a later process; in the meanwhile, the redistribution layer is made to have a second side with metal pads adapted to be electrically coupled to a mother board. A metal sputtering or metal evaporating is performed in the initial step to form a plurality of metal pads with stable dimension so that the bottom side of the plurality of metal pads is adapted to electrically couple to a nanochip in a later process.

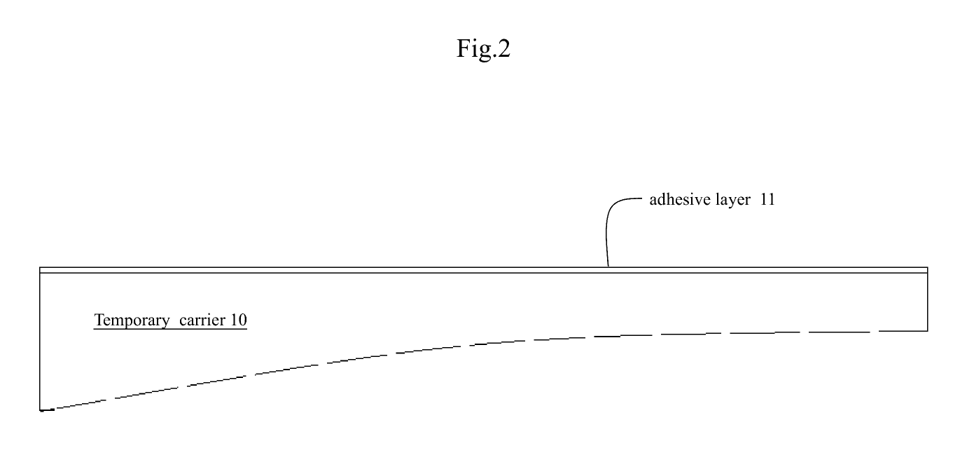

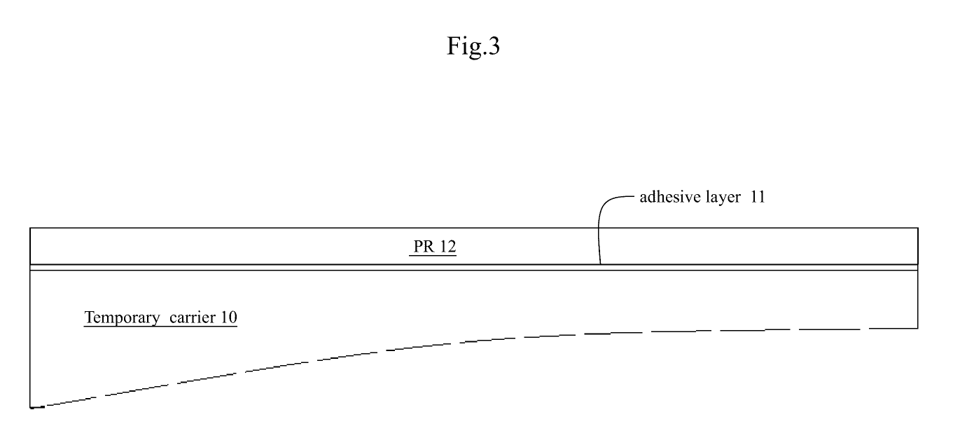

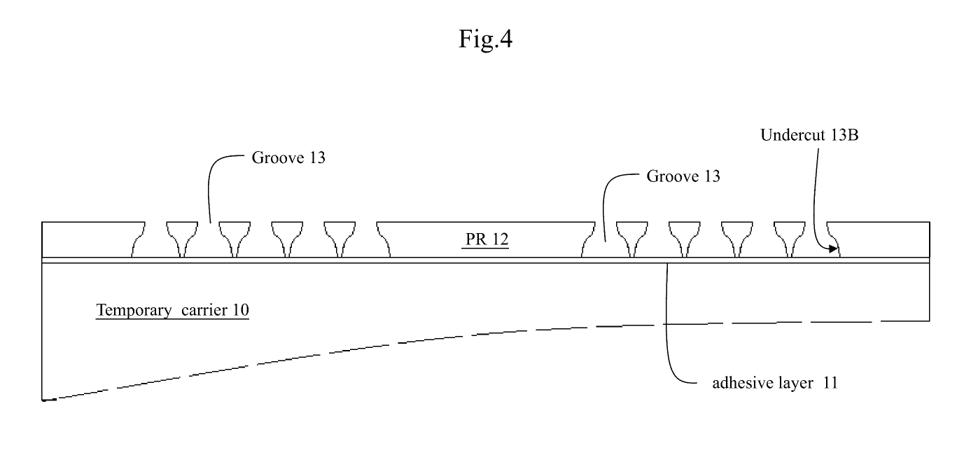

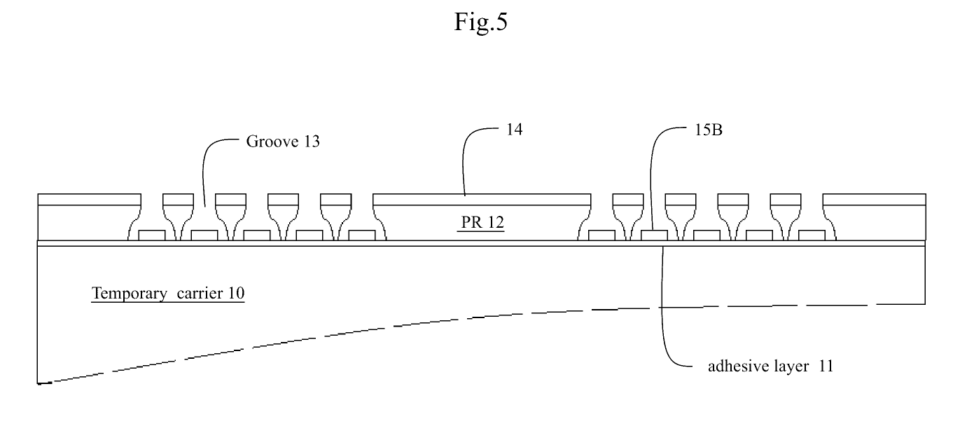

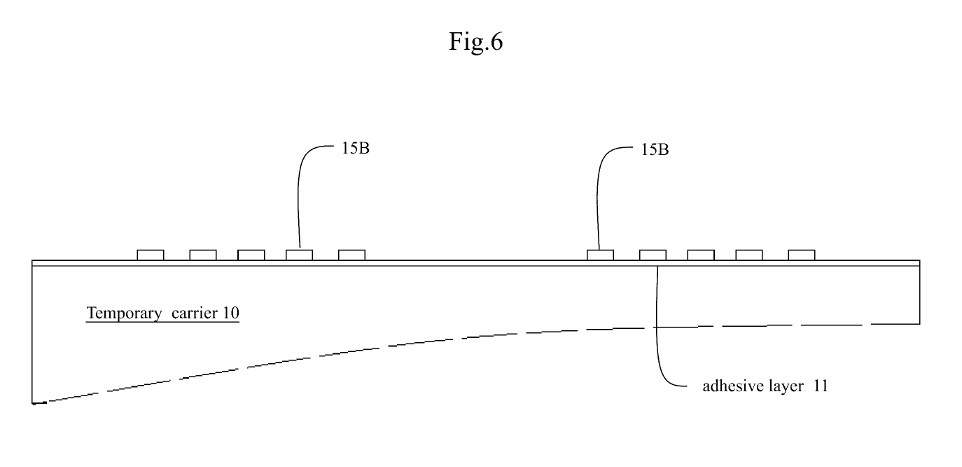

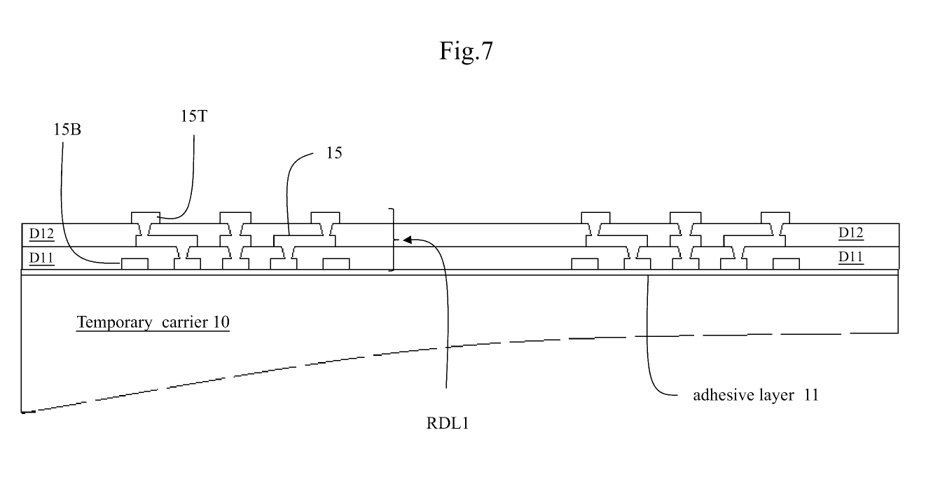

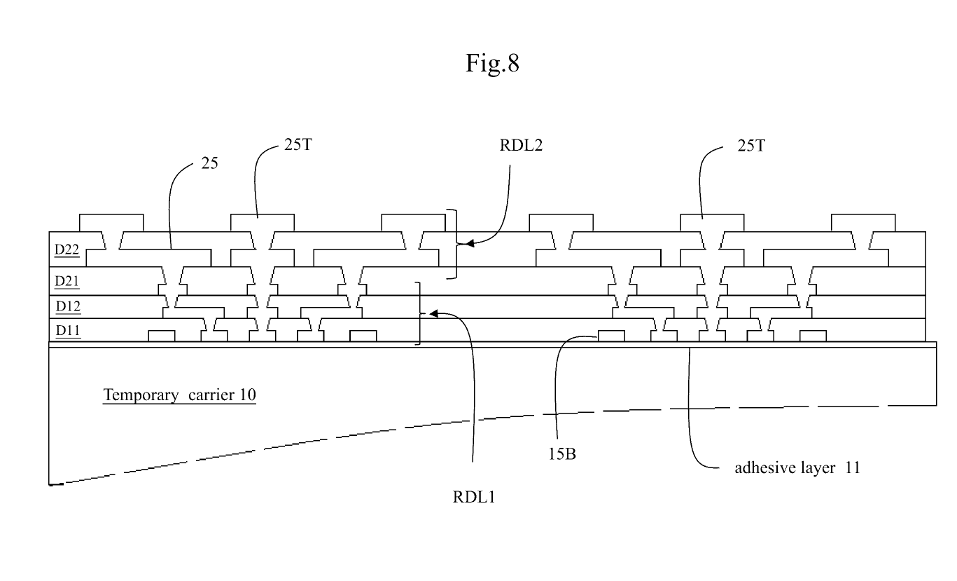

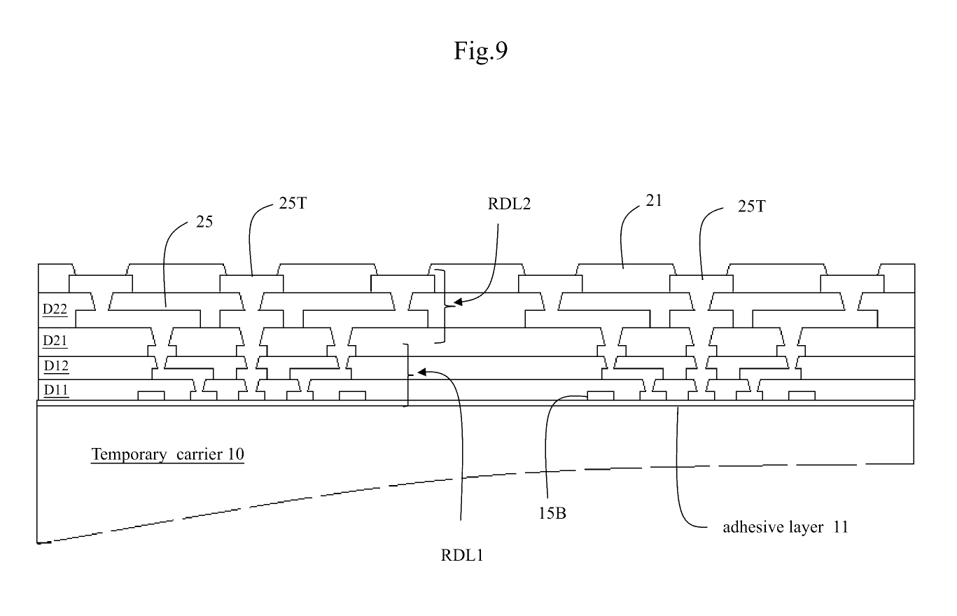

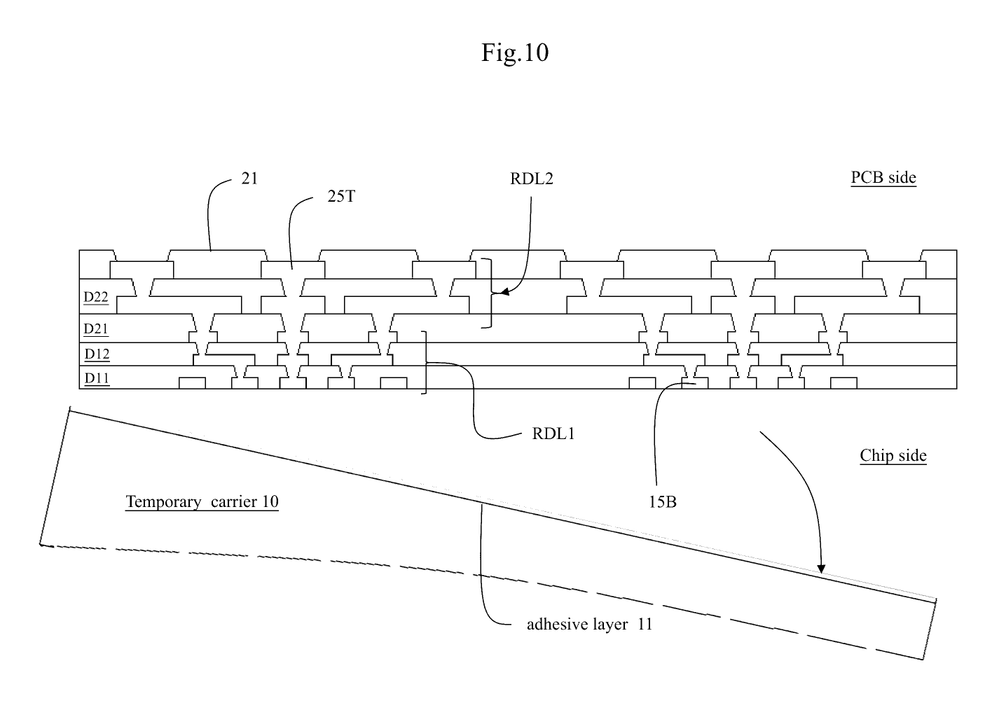

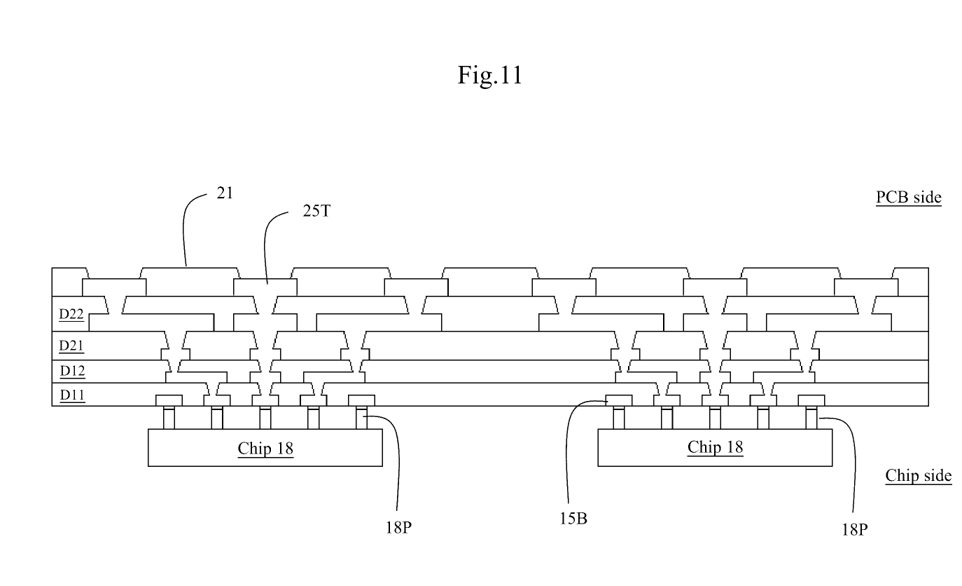

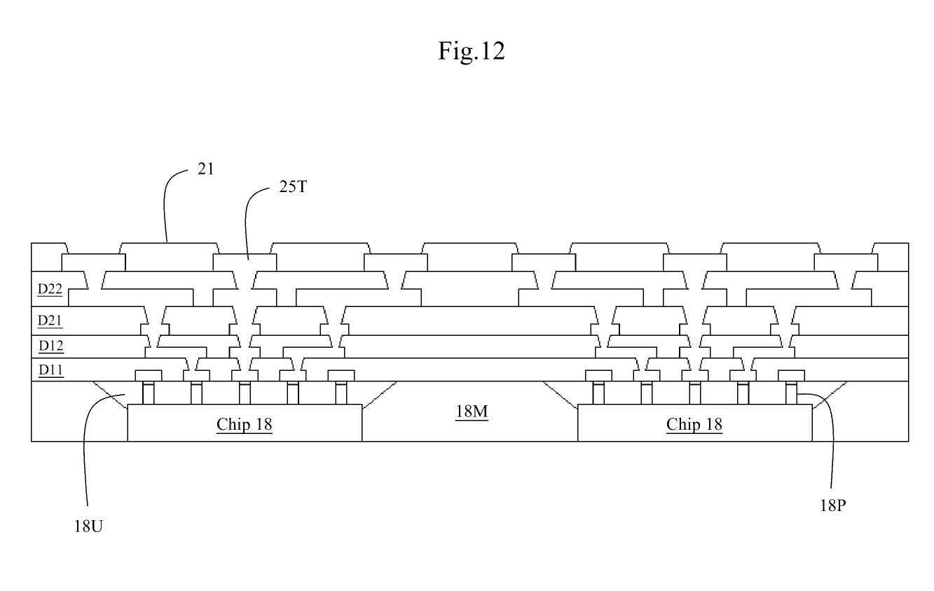

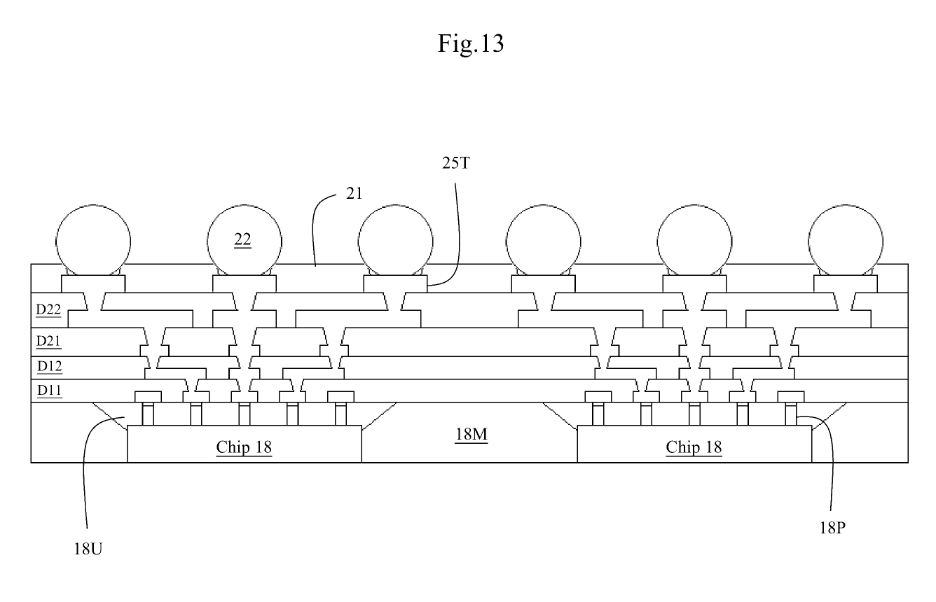

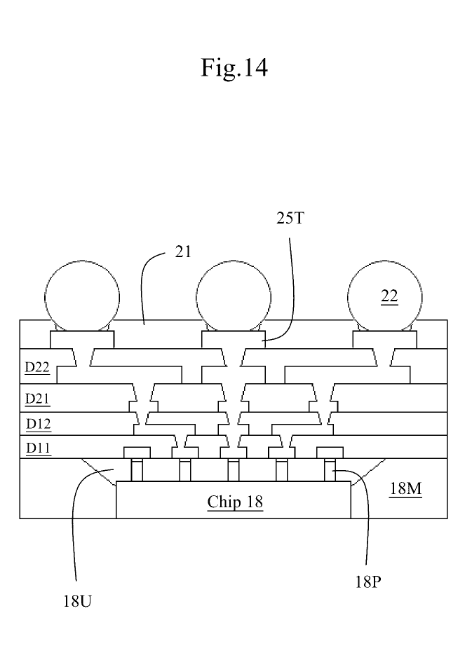

FIGS. 2˜14 show a fabricating process for a redistribution layer according to the present invention.

FIG. 2 shows:

preparing a temporary carrier 10 with an adhesive layer 11 formed on a top surface of the temporary carrier 10;

FIG. 3 shows:

applying photoresist (PR) 12 on a top surface of the adhesive layer 11;

FIG. 4 shows:

patterning the photoresist (PR) 12 to form a plurality of grooves 13 with undercut 13B formed at a bottom of each groove 13, and to reveal a top surface of the adhesive layer 11 at the bottom of each groove 13;

FIG. 5 shows:

Sputtering or evaporating a metal, e.g. copper, to form metal pads 14 on a top surface of the photoresist (PR) 12, and to form metal pads 15B on the top surface of the exposed adhesive layer 11 at the bottom of each groove 13;

FIG. 6 shows:

stripping the photoresist (PR) 12 to leave a plurality of bottom metal pads 15B on the top surface of the adhesive layer 11;

FIG. 7 shows:

forming a first redistribution circuitry 15 on a top of the plurality of bottom metal pads 15B to fan out the circuitry density upwards. The first redistribution circuitry 15 is embedded in a first dielectric layers D11, D12. The first redistribution circuitry 15 has a plurality of first top metal pads 15T configured on a top surface of the dielectric layer D12. A density of the first bottom metal pads 15B is higher than a density of the first top metal pads 15T. The first redistribution circuitry 15 plus the first dielectric layers D11, D12 is collectively referred to a first redistribution layer (RDL1).

FIG. 8 shows:

forming a second redistribution circuitry 25 on a top of the first redistribution circuitry 15 to further fan out the circuitry density upwards; the second redistribution circuitry 25 is embedded in a second dielectric layers D21, D22. The second redistribution circuitry 25 has a plurality of second top metal pads 25T configured on a top surface of the dielectric layer D22. A density of the first top metal pads 15T is higher than a density of the second top metal pads 25T. The second redistribution circuitry 25 plus the second dielectric layer D21, D22 is collectively referred to a second redistribution layer (RDL2).

FIG. 9 shows:

forming a passivation layer 21 on a top surface of the second top meta pads 25T to expose a central area of each second top metal pad 25T.

FIG. 10 shows:

removing the temporary carrier 10 and the adhesive layer 11.

A top side of the redistribution layer is a PCB side and the bottom side of the redistribution layer is a chip side.

FIG. 11 shows:

mounting a chip 18 on a bottom of the first bottom metal pads 15B through a plurality of metal pillar 18P which are configured on a top surface of the chip 18.

FIG. 12 shows:

Underfilling a space between the chip 18 and the first bottom metal pads 15B with a sealing material 18U; and molding the chip 18 with a molding compound 18M.

FIG. 13 shows:

planting a plurality of solder balls 22, each configured on a top of a corresponding second top metal pads 25T.

FIG. 14 shows:

FIG. 14 shows a single unit of chip package according to the present invention.

FIG. 14 is obtained from singulating the product of FIG. 13.

While several embodiments have been described by way of example, it will be apparent to those skilled in the art that various modifications may be configured without departs from the spirit of the present invention. Such modifications are all within the scope of the present invention, as defined by the appended claims.

What is claimed is:

1. A fabricating process for a redistribution layer, comprising:
preparing a temporary carrier with an adhesive layer formed on a top surface of the temporary carrier;
applying photoresist on a top surface of the adhesive layer;
patterning the photoresist to form a plurality of grooves with undercut at a bottom of each groove, and to reveal a top surface of the adhesive layer at the bottom of each groove;
sputtering or evaporating to form metal on a top surface of the exposed adhesive layer at the bottom of each groove; and
stripping the photoresist to leave a plurality of first bottom metal pads on the top surface of the adhesive layer.

2. A fabricating process for a redistribution layer as claimed in claim 1, further comprising:
a first redistribution circuitry formed on a top surface of the plurality of first bottom metal pads; and
a second redistribution circuitry formed on a top surface of the first redistribution circuitry.

3. A fabricating process for a redistribution layer as claimed in claim 2, further comprising:
removing the temporary carrier and the adhesive layer.

4. A fabricating process for a redistribution layer as claimed in claim 3, further comprising:
mounting a chip on a bottom surface of the plurality of first bottom metal pads.

5. A fabricating process for a redistribution layer as claimed in claim 4, further comprising:
planting a plurality of solder balls, each configured on a top surface of a corresponding second top metal pad.
